(19) United States
(12) Patent Application Publication
(10) Pub. No.: US 2019/0181119 A1
(43) Pub. Date: Jun. 13, 2019

(54) STACKED SEMICONDUCTOR DEVICE AND METHOD FOR FORMING THE SAME

(71) Applicant: UNITED MICROELECTRONICS CORP., Hsinchu (TW)

(72) Inventors: Guo-Zhong Xing, Singapore (SG); Chien-En Hsu, Singapore (SG)

(21) Appl. No.: 15/834,519

(22) Filed: Dec. 7, 2017

(51) Int. Cl. H01L 25/065; H01L 23/00; H01L 23/48; H01L 25/00

(52) U.S. Cl. CPC H01L 25/0657; H01L 27/14634; H01L 23/481; H01L 25/50; H01L 24/83; H01L 2224/32146; H01L 2225/06527; H01L 2224/29186; H01L 2224/83896; H01L 2224/83191; H01L 2224/83193; H01L 2225/06541; H01L 2225/06565; H01L 2224/83951; H01L 24/32

(57) ABSTRACT

A stacked semiconductor device is provided, including a first semiconductor structure, a second semiconductor structure and a bonding structure disposed between the first and second semiconductor structures. The first semiconductor structure and the second semiconductor structure include first conductive pillars and second conductive pillars, respectively. The first semiconductor structure is stacked above the second semiconductor structure. The bonding structure contacts the first conductive pillars and the second conductive pillars, wherein the bonding structure comprises conductive paths for electrically connecting the first conductive pillars and the second conductive pillars.

### BACKGROUND

### Technical Field

The disclosure relates in general to a semiconductor device and a method for forming the same, and more particularly to a stacked semiconductor device and a method for forming the same.

### Description of the Related Art

Reduction of feature size, improvements of the rate, the efficiency, the density and the cost per integrated circuit unit are the important goals in the advanced semiconductor technology development. The electrical properties of the device have to be maintained even improved to meet the requirements of the commercial product applications in minimization with scaling down the size. The layers and components with defects (such as position misalignment, incomplete profiles) and process complexity would induce considerable impact on the performance of the device and yield of production.

For example, during the fabrication of a conventional stacked semiconductor device, two semiconductors in a stack are connected by fusion bonding a couple of hybrid structures consisting conductive pillars (e.g., Cu) and inter-metal dielectrics (IMD) which are pre-formed in the corresponding two semiconductor counterparts. This conventional bonding method suffers from several severe problems with challenges, such as the alignment accuracy for bonding conductive pillars, the dedicated control of bonding surface roughness and the Cu oxidation Q-time control before bonding. Mis-alignment of the semiconductor structures, unqualified bonding surface roughness and Cu oxidation before bonding would lead considerable deterioration on the electrical performance of the stacked semiconductor devices.

### SUMMARY

The disclosure is directed to a stacked semiconductor device, and a method for forming the same, wherein a bonding structure disposed between two semiconductor structures is provided. The bonding structure not only acts as a bonding medium for stacking two semiconductor structures, but also provides the well-defined conductive paths for electrically connecting two semiconductor structures.

According to one aspect of the present disclosure, a stacked semiconductor device is provided, comprising a first semiconductor structure, comprising first conductive pillars; a second semiconductor structure, comprising second conductive pillars, and the first semiconductor structure stacked above the second semiconductor structure; and a bonding structure, disposed between the first semiconductor structure and the second semiconductor structure, and contacting the first conductive pillars and the second conductive pillars, wherein the bonding structure comprises conductive paths for electrically connecting the first conductive pillars and the second conductive pillars.

According to another aspect of the present disclosure, a method for forming a stacked semiconductor device is provided, comprising: providing a first semiconductor structure having first conductive pillars; providing a second semiconductor structure having second conductive pillars; and forming a bonding structure between the first semiconductor structure and the second semiconductor structure, and the bonding structure contacting the first conductive pillars and the second conductive pillars, wherein the bonding structure comprises conductive paths for electrically connecting the first conductive pillars and the second conductive pillars.

### BRIEF DESCRIPTION OF THE DRAWINGS

FIG. 1 illustrates a stacked semiconductor device according to one embodiment of the disclosure.

FIG. 2 demonstrates a flow of a method for forming a stacked semiconductor device according to one embodiment of the disclosure.

FIG. 3A and FIG. 3B illustrate a method for forming a stacked semiconductor device before and after forming conductive paths according to one embodiment of the disclosure.

FIG. 4 depicts an exemplified flow for forming an embodied stacked semiconductor device.

In the following detailed description, for purposes of explanation, the specific details are set forth in order to provide an overall clear picture and further warrant a thorough understanding of the disclosed embodiments. They are illustrated schematically and systematically to the most of extent, while one or more embodiments might be practiced without those specific details. In other instances, the well-known structures and devices are schematically shown in order to simplify the drawing.

### DETAILED DESCRIPTION

In the embodiment of the present disclosure, a stacked semiconductor device and a method for forming the same are provided. According to the embodiments, a bonding structure disposed between two semiconductor structures is provided, wherein the bonding structure not only acts as a bonding medium for stacking two semiconductor structures, but also provides the conductive paths for electrically connecting two semiconductor structures. The embodied structural configuration and method thereof would solve the conventional problems such as alignment accuracy for bonding, control of bonding surface roughness and Cu oxidation Q-time control before bonding. Moreover, it takes a very short time (e.g., couples milliseconds) for conducting a forming process (i.e., an electrical forming process) to create conductive filaments between the two semiconductor structures according to an embodied method.

The embodiments can be applied to bond different types of semiconductor devices. Embodiments are provided hereinafter with reference to the accompanying drawings for describing the related procedures and configurations. It is noted that not all embodiments of the invention are shown. There may be other embodiments of the present disclosure which are not specifically illustrated. Also, modifications and variations can be made without departing from the spirit of the disclosure to meet the requirements of the practical applications. It is also important to point out that the illustrations may not necessarily be drawn to scale. Thus, the specification and the drawings are to be regard as an illustrative sense rather than a restrictive sense.

Moreover, use of ordinal terms such as “first”, “second”, “third” etc., in the specification and claims to describe an element does not by itself connote any priority, precedence, or order of one claim element over another or the temporal order in which acts of a method are performed, but are used merely as labels to distinguish one claim element having a certain name from another element having the same name (but for use of the ordinal term) to distinguish the claim elements.

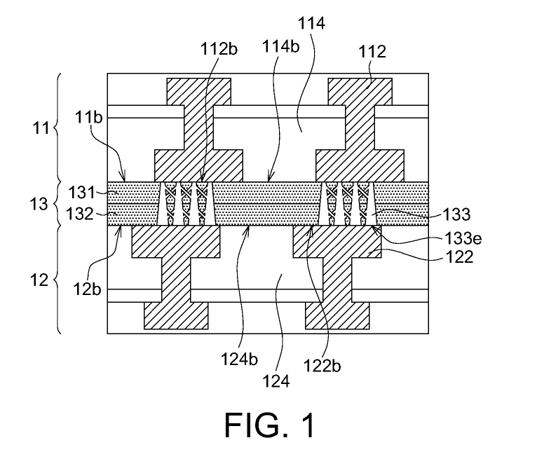

FIG. 1 illustrates a stacked semiconductor device according to one embodiment of the disclosure. In one embodiment, a stacked semiconductor device comprises a first semiconductor structure 11, a second semiconductor structure 12 and a bonding structure 13, as shown in FIG. 1. The first semiconductor structure 11 comprises first conductive pillars 112. The second semiconductor structure 12 comprises second conductive pillars 122, and the first semiconductor structure 11 is stacked above the second semiconductor structure 12. The bonding structure 13 is disposed between the first semiconductor structure 11 and the second semiconductor structure 12, and the bonding structure 13 contacts the first conductive pillars 112 and the second conductive pillars 122, respectively. According to the embodiment, the bonding structure 13 comprises conductive paths 133 for electrically connecting the first conductive pillars 112 and the second conductive pillars 122.

In one embodiment, the bonding structure 13 comprises a first bonding layer 131 and a second bonding layer 132, wherein the first bonding layer 131 is disposed at a first bottom surface 11b of the first semiconductor structure 11, and the second bonding layer 132 is disposed at a second bottom surface 12b of the second semiconductor structure 12. The first bonding layer 131 directly contacts the second bonding layer 132. In one embodiment, the conductive paths 133 extend to penetrate through the first bonding layer 131 and the second bonding layer 132 for electrically connecting the first conductive pillars 112 and the second conductive pillars 122, thereby electrically connecting the first semiconductor structure 11 and the second semiconductor structure 12.

In one example, the first conductive pillars 112 and the second conductive pillars 122 can be, but not limited to, Cu pillars. Also, the first conductive pillars 112 are positioned correspondingly to the second conductive pillars 122; for example, it is applicable that the first conductive pillars 112 and the second conductive pillars 122 are substantially aligned or partially overlapped (slightly mis-aligned or shifted) to each other.

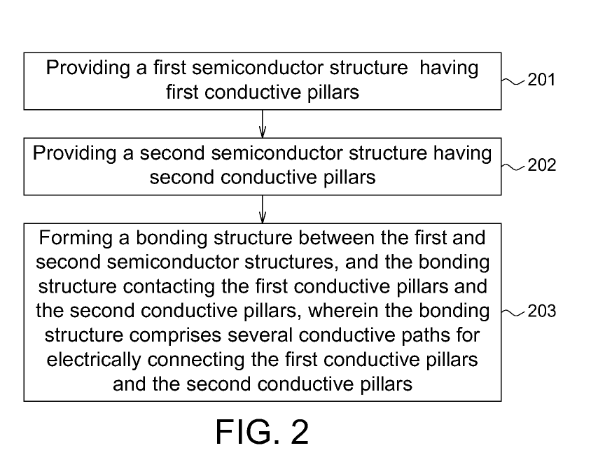

FIG. 2 demonstrates a flow of a method for forming a stacked semiconductor device according to one embodiment of the disclosure. Please also refer to FIG. 1. According to an embodiment, a method of forming a stacked semiconductor device comprises steps of step 201, step 202, and step 203. In step 201, a first semiconductor structure 11, e.g., a first wafer, having first conductive pillars 112, (e.g., Cu pillar) is provided. In step 202, a second semiconductor structure 12, (e.g., a second wafer) having second conductive pillars 122 (e.g., Cu pillar) is provided. In step 203, a bonding structure 13 between the first semiconductor structure 11 and the second semiconductor structure 12 is formed. The bonding structure 13 contacts the first conductive pillars 112 and the second conductive pillars 122, wherein the bonding structure 13 comprises several conductive paths 133 for electrically connecting the first conductive pillars 112 and the second conductive pillars 122.

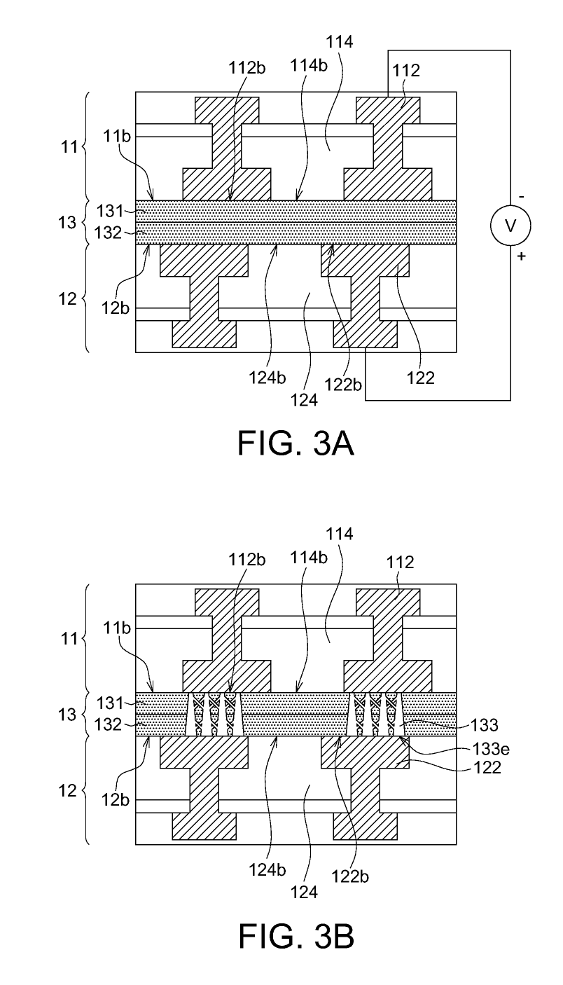

FIG. 3A and FIG. 3B illustrate a method for forming a stacked semiconductor device before and after forming conductive paths according to one embodiment of the disclosure. Please also refer to FIG. 1. The identical and/or similar elements of FIG. 1 and FIG. 3A and FIG. 3B are designated with the same and/or similar reference numerals.

As shown in FIG. 3A, the first bonding layer 131 is disposed at the first bottom surface 11b of the first semiconductor structure 11, and the second bonding layer 132 is disposed at the second bottom surface 12b of the second semiconductor structure 12, wherein the first bonding layer 131 directly contacts and connects the second bonding layer 132 for stacking the first semiconductor structure 11 on the second semiconductor structure 12.

In one embodiment, the bonding structure 13 comprises at least a transition metal oxide layer. For example, the first bonding layer 131 and the second bonding layer 132 are transition metal oxide (TMO) layers. In one but not limited example, the bonding structure 13 comprises an oxide of transition metals such as vanadium (V), niobium (Nb), titanium (Ti), iron (Fe), tantalum (Ta), tungsten (W), zirconium (Zr), hafnium (Hf) and molybdenum (Mo). Among these transition metal oxide materials, TaO has the characteristic of low electrical resistance of 10⁻⁵˜10⁻⁴ ohm·cm, and thus TaO is the preferred transition metal oxide for being the material of the bonding layer. Moreover, the first bonding layer 131 and the second bonding layer 132 may comprise the same material, such as the same transition metal oxide. However, the disclosure is not limited the same.

In addition, the first semiconductor structure 11 of an embodiment further comprises a first insulating layer 114, and the first conductive pillars 112 are buried in the first insulating layer 114, as shown in FIG. 1 and FIG. 3B. Similarly, the second semiconductor structure 12 of an embodiment further comprises a second insulating layer 124, and the second conductive pillars 122 are buried in the second insulating layer 124. In one embodiment, the first bottom surface 11b of the first semiconductor structure 11 is comprised of first exposed surfaces 112b of the first conductive pillars 112 and a first lower surface 114b of the first insulating layer 114. Similarly, the second bottom surface 12b of the second semiconductor structure 12 is comprised of second exposed surfaces 122b of the second conductive pillars 122 and a second lower surface 124b of the second insulating layer 124. After stacking, the first bonding layer 131 directly contacts and covers the first exposed surfaces 112b of the first conductive pillars 112 and the first lower surface 114b of the first insulating layer 114. Similarly, the second bonding layer 132 directly contacts and covers the second exposed surfaces 122b of the second conductive pillars 122 and the second lower surface 124b of the second insulating layer 124.

According to one embodied method, a forming process (also referred as an electrical forming process conducted in a typical resistive switching device for growing conductive filaments) can be performed by applying an appropriate voltage (also referred as a forming bias conducted in a typical resistive switching device) to the first conductive pillars 112 and the second conductive pillars 122 after stacking the second semiconductor structure 12 and the first semiconductor structure 11. Accordingly, a plurality of conductive filaments (e.g., the conductive paths 133) are formed between the first semiconductor structure 11 and the second semiconductor structure 12 after forming process, as shown in FIG. 3B. Therefore, the conductive filaments penetrate the first bonding layer 131 and the second bonding layer 132, and function as the conductive paths 133 between the two semiconductor structures. In other words, the conductive paths 133 (e.g., conductive filaments) of the embodiment can be created by subjecting the transition metal oxide layers under a forming process (i.e., an electrical forming process). In one embodiment, two opposite ends 133e of the conductive paths 133 (e.g., conductive filaments) contact the first conductive pillars 112 and the second conductive pillars 122, respectively, for creating the paths for electric current passing through.

It is noted that a SET process and a RESET process typically adopted in a resistive-switching device (for switching the resistance of the device between HRS (high resistance state) and LRS (low resistance state) are not performed in the embodiment. Only a forming process (also referred as an electrical forming process conducted in a typical resistive switching device) is adopted for creating the conductive filaments in the bonding structure 13. As soon as the conductive filaments are formed to connect the first conductive pillars 112 and the second conductive pillars 122, the conductive paths between two semiconductor structures are constructed permanently.

Furthermore, in the practical application, the first semiconductor structure 11 and the second semiconductor structure 12 can be, but not limited to, two wafers with similar or different functions. In one example, the first semiconductor structure 11 can be a CMOS image sensor (CIS) wafer, and the second semiconductor structure 12 can be an image signal processor (ISP) wafer. It is noted that the exemplified drawings FIG. 1, FIG. 3A, and FIG. 3B, wherein the conductive pillars for bonding the semiconductor structures are depicted, can clearly illustrate the invention. Configurations of other components in the first and second semiconductor structures, (e.g., components of CMOS image sensor (CIS) and image signal processor (ISP) in one application) would be varied and determined according to the requirements of the practical applications. Therefore, there are no specific limitations for the types of the first and second semiconductor structures in the present disclosure.

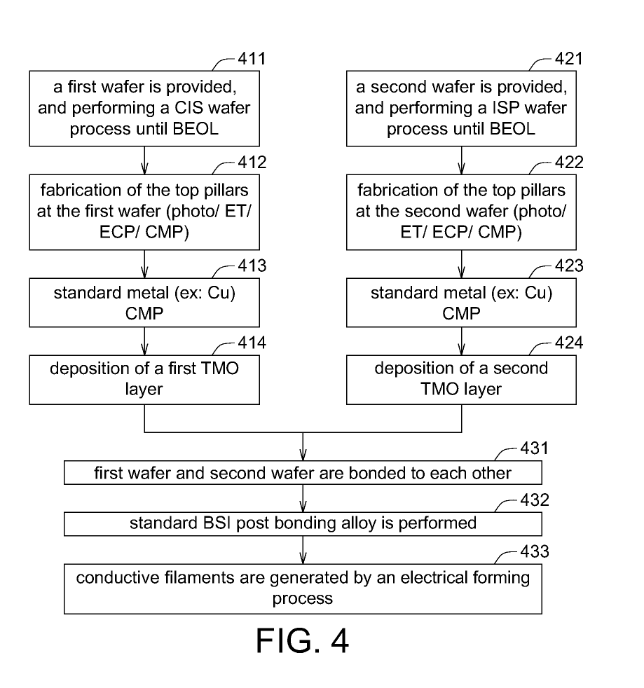

FIG. 4 is an exemplified flow for forming an embodied stacked semiconductor device. One of the applications for bonding and connecting a CIS wafer and an ISP wafer is exemplified for illustration, not for limitation. In step 411, a first wafer is provided, and a CIS wafer process is performed at the first wafer until back end of line (BEOL). Then, in step 412, fabrication of the top pillars at the first wafer, such as photolithography, etching (ET), electrical chemical plating (ECP) and chemical mechanical polishing (CMP), is performed. The aforementioned top pillars can be metal pillars, such as Cu pillars. Next, step 412 is followed by step 413 which shows standard metal CMP. The standard metal CMP can be the standard Cu CMP. A first semiconductor structure having the first conductive pillars of the embodiment has been provided so far. Next, in step 414, deposition of a first TMO layer (e.g., the first bonding layer 131) on the top pillars at the first wafer is performed. Similarly, in step 421, a second wafer is provided, and an ISP wafer process is performed at the second wafer until BEOL. Then, in step 422, fabrication of the top pillars (metal pillars such as Cu pillars) at the second wafer, such as photolithography, etching (ET), electrical chemical plating (ECP) and chemical mechanical polishing (CMP), is performed. Step 422 is followed by step 423 which shows the standard metal CMP. The standard metal CMP can be the standard Cu CMP. After performing steps 421, 422, and 423, a second semiconductor structure having the second conductive pillars of the embodiment has been provided so far. Next, in step 424, deposition of a second TMO layer (e.g., the second bonding layer 132) on the top pillars at the second wafer is performed. Afterwards, in step 431, the first wafer and the second wafer having different functions are bonded to each other. After that, in step 432, a standard BSI (back side illumination) post bonding alloy is performed. Finally, in step 433, conductive filaments are generated by an electrical forming process before wafer out.

According to the aforementioned descriptions, a bonding structure is disposed between two semiconductor structures, wherein the bonding structure not only acts as a bonding medium for stacking two semiconductor structures, but also provides the conductive paths for electrically connecting two semiconductor structures. According to the embodiment, since the bonding structure (e.g., a first bonding layer and a second bonding layer) extends over the bottom surfaces of two semiconductor structures entirely, the exposed surfaces of the Cu pillars and the lower surfaces of the insulating layers surrounding the Cu pillars are covered by the bonding layer (e.g., TMO layer) and it would be easier to complete the bonding. Also, according to the embodiment, since the bonding step is performed between the first bonding layer and the second bonding layer, there is no need to control surface roughness of the exposed surfaces of the Cu pillars, and the conventional Cu oxidation Q-time control step before bonding can be canceled. Therefore, the embodied structure and forming method solve the conventional problems such as alignment accuracy for bonding, control of bonding surface roughness and Cu oxidation Q-time control before bonding. Moreover, it takes a very short time (e.g., couples milliseconds) for conducting a forming process to create conductive filaments between the two semiconductor structures.

Other embodiments with different configurations of known elements in the semiconductor structures can be applicable, and the arrangement of the elements depends on the actual needs of the practical applications. It is, of course, noted that the configurations of figures are depicted only for demonstration, not for limitation. It is known by people skilled in the art that the shapes or positional relationship of the constituting elements and the procedure details could be adjusted according to the requirements and/or manufacturing steps of the practical applications without departing from the spirit of the disclosure.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A stacked semiconductor device, comprising:
a first semiconductor structure, comprising first conductive pillars;
a second semiconductor structure, comprising second conductive pillars, and the first semiconductor structure stacked above the second semiconductor structure; and
a bonding structure, disposed between the first semiconductor structure and the second semiconductor structure, and contacting the first conductive pillars and the second conductive pillars,
wherein the bonding structure comprises conductive paths for electrically connecting the first conductive pillars and the second conductive pillars.

2. The stacked semiconductor device according to claim 1, wherein the bonding structure comprises:
a first bonding layer, disposed at a first bottom surface of the first semiconductor structure; and
a second bonding layer, disposed at a second bottom surface of the second semiconductor structure,
wherein the first bonding layer directly contacts the second bonding layer.

3. The stacked semiconductor device according to claim 2, wherein the conductive paths extend to penetrate through the first bonding layer and the second bonding layer for electrically connecting the first conductive pillars and the second conductive pillars.

4. The stacked semiconductor device according to claim 2, wherein the first semiconductor structure comprises a first insulating layer, and the first conductive pillars are buried in the first insulating layer; and
the second semiconductor structure comprises a second insulating layer, and the second conductive pillars are buried in the second insulating layer.

5. The stacked semiconductor device according to claim 4, wherein the first bottom surface of the first semiconductor structure is comprised of first exposed surfaces of the first conductive pillars and a first lower surface of the first insulating layer; and
the second bottom surface of the second semiconductor structure is comprised of second exposed surfaces of the second conductive pillars and a second lower surface of the second insulating layer.

6. The stacked semiconductor device according to claim 5, wherein the first bonding layer directly contacts and covers the first exposed surfaces of the first conductive pillars and the first lower surface of the first insulating layer; and
the second bonding layer directly contacts and covers the second exposed surfaces of the second conductive pillars and the second lower surface of the second insulating layer.

7. The stacked semiconductor device according to claim 1, wherein the bonding structure comprises at least a transition metal oxide layer, and the conductive paths are conductive filaments formed in the bonding structure.

8. The stacked semiconductor device according to claim 1, wherein the bonding structure comprises an oxide of transition metals selected from a group consisting of vanadium (V), niobium (Nb), titanium (Ti), iron (Fe), tantalum (Ta), tungsten (W), zirconium (Zr), hafnium (Hf) and molybdenum (Mo).

9. A method of forming a stacked semiconductor device, comprising:
providing a first semiconductor structure having first conductive pillars;
providing a second semiconductor structure having second conductive pillars; and
forming a bonding structure between the first semiconductor structure and the second semiconductor structure, and the bonding structure contacting the first conductive pillars and the second conductive pillars, wherein the bonding structure comprises conductive paths for electrically connecting the first conductive pillars and the second conductive pillars.

10. The method according to claim 9, wherein the bonding structure comprises at least a transition metal oxide layer, and the conductive paths are conductive filaments created by subjecting the transition metal oxide layer to a forming process.

11. The method according to claim 9, wherein the bonding structure comprises:
a first bonding layer, disposed at a first bottom surface of the first semiconductor structure; and
a second bonding layer, disposed at a second bottom surface of the second semiconductor structure,
wherein the first bonding layer directly contacts and connects the second bonding layer.

12. The method according to claim 11, wherein the conductive paths extend to penetrate through the first bonding layer and the second bonding layer for electrically connecting the first conductive pillars and the second conductive pillars.

13. The method according to claim 11, wherein the first semiconductor structure comprises a first insulating layer, and the first conductive pillars are buried in the first insulating layer; and
the second semiconductor structure comprises a second insulating layer, and the second conductive pillars are buried in the second insulating layer.

14. The method according to claim 13, wherein the first bottom surface of the first semiconductor structure is comprised of first exposed surfaces of the first conductive pillars and a first lower surface of the first insulating layer; and
the second bottom surface of the second semiconductor structure is comprised of second exposed surfaces of the second conductive pillars and a second lower surface of the second insulating layer.

15. The method according to claim 14, wherein the first bonding layer directly contacts and covers the first exposed surfaces of the first conductive pillars and the first lower surface of the first insulating layer; and
the second bonding layer directly contacts and covers the second exposed surfaces of the second conductive pillars and the second lower surface of the second insulating layer.

16. The method according to claim 9, wherein the bonding structure comprises an oxide of transition metals selected from a group consisting of vanadium (V), niobium (Nb), titanium (Ti), iron (Fe), tantalum (Ta), tungsten (W), zirconium (Zr), hafnium (Hf) and molybdenum (Mo).
